(19) United States
(12) Patent Application Publication
(10) Pub. No.: US 2014/0211822 A1
(43) Pub. Date: Jul. 31, 2014

(54) VERTICAL-CAVITY SURFACE-EMITTING LASERS

(71) Applicants: David A. Fattal, Mountain View, CA (US); Michael Renne Ty Tan, Monlo Park, CA (US); Raymond G. Beausoleil, Redmond, WA (US)

(72) Inventors: David A. Fattal, Mountain View, CA (US); Michael Renne Ty Tan, Monlo Park, CA (US); Raymond G. Beausoleil, Redmond, WA (US)

(21) Appl. No.: 14/342,762

(22) PCT Filed: Sep. 15, 2011
(86) PCT No.: PCT/US2011/051833

§ 371 Date: Mar. 4, 2014

(51) Int. Cl. H01S 5/183; H01S 5/187

(52) U.S. Cl. CPC H01S 5/183; H01S 5/187
USPC 372/45.01

(57) ABSTRACT

Vertical-cavity surface-emitting lasers (“VCSELs”) and VCSEL arrays are disclosed. In one aspect, a surface-emitting laser includes a grating layer having a sub-wavelength grating to form a resonant cavity with a reflective layer for a wavelength of light to be emitted from a light-emitting layer and an aperture layer disposed within the resonant cavity. The VCSEL includes a charge carrier transport layer disposed between the grating layer and the light-emitting layer. The transport layer has a gap adjacent to the sub-wavelength grating and a spacer region between the gap and the light-emitting layer. The spacer region and gap are dimensioned to be substantially transparent to the wavelength. The aperture layer directs charge carriers to enter a region of the light-emitting layer adjacent to an aperture in the aperture layer and the aperture confines optical modes to be emitted from the light-emitting layer.

### BACKGROUND

Semiconductor lasers represent one of the most important class of lasers in use today because they can be used in a wide variety of systems including displays, solid-state lighting, sensors, printers, and telecommunications just to name a few. The two types of semiconductor lasers primarily in use are edge-emitting lasers and surface-emitting lasers. Edge-emitting lasers generate light traveling in a direction substantially parallel to a light-emitting layer. On the other hand, surface-emitting lasers generate light traveling normal to the light-emitting layer. Surface-emitting layers have a number of advantages over typical edge-emitting lasers: they emit light more efficiently and can be arranged in two-dimensional, light-emitting arrays.

The light-emitting layer of a typical surface-emitting laser is sandwiched between two reflectors and the lasers are referred to as vertical-cavity surface-emitting lasers (“VCSELs”). The reflectors are typically distributed Bragg reflectors (“DBRs”) that ideally form a resonant cavity with greater than 99% reflectivity for optical feedback. DBRs are composed of multiple alternating dielectric or semiconductor layers with periodic refractive index variation. Two adjacent layers within a DBR have different refractive indices and are referred to as “DBR pairs.” DBR reflectivity and bandwidth depend on the refractive-index contrast of constituent materials of each layer and on the thickness of each layer. The materials used to form DBR pairs typically have similar compositions and, therefore, have relatively small refractive-index differences. Thus, in order to achieve a cavity reflectivity of greater than 99%, and provide a narrow mirror bandwidth, DBRs have anywhere from about 15 to about 40 or more DBR pairs. However, fabricating DBRs with greater than 99% reflectivity has proven to be difficult, especially for VCSELs designed to emit light with wavelengths in the blue-green and long-infrared portions of the electromagnetic spectrum.

Physicists and engineers continue to seek improvements in VCSEL design, operation, and efficiency.

### BRIEF DESCRIPTION OF THE DRAWINGS

FIGS. 1A-1B show an isometric view and an exploded isometric view, respectively, of an example VCSEL.

FIG. 2 shows a cross-sectional view along a line I-I of the VCSEL shown in FIG. 1A.

FIG. 3 shows an exploded isometric view of a grating layer of the VCSEL shown in FIG. 1.

FIG. 4 shows a plot of reflectance and phase shift over a range of wavelengths for one-dimensional sub-wavelength gratings.

FIG. 5 shows a cross-sectional view of the VCSEL, shown in FIG. 1, connected to a voltage source.

FIG. 6 shows a representation of standing electromagnetic waves in a resonant cavity of the VCSEL shown in FIG. 1.

FIG. 7 shows a cross-sectional view of the VCSEL shown in FIG. 1 with a representation of an output beam.

FIG. 8A shows example intensity profiles of three transverse modes in a resonant cavity of the VCSEL shown in FIG. 1.

FIGS. 8B-8C show plots of resonance wavelengths and quality factors versus aperture diameters of an aperture layer of a VCSEL.

FIG. 9 shows example intensity profile versus wavelength plots of a light-emitting layer of the VCSEL shown in FIG. 1.

FIG. 10A shows a cross-sectional view of an example VCSEL.

FIG. 10B shows a cross-sectional view of an example VCSEL.

FIGS. 11A-11B show an isometric view and a cross-sectional view, respectively, of an example VCSEL array.

FIG. 12 shows example intensity profiles versus wavelength plots of light emitted from light-emitting layers of the VCSEL array shown in FIG. 11.

### DETAILED DESCRIPTION

Vertical-cavity surface-emitting lasers (“VCSELs”) and VCSEL arrays are disclosed. Each VCSEL whether a standalone VCSEL or a VCSEL in a VCSEL array includes a dielectric aperture layer and a sub-wavelength grating (“SWG”). The SWG is one of the reflective surfaces of the VCSEL resonant cavity. The SWG pattern is selected so that a beam of light is output from the VCSEL with a desired wavelength. An aperture in the aperture layer of each VCSEL confines optical modes and electrical current in the transverse direction. In general, each VCSEL has a small mode volume, an approximately single spatial output mode, emit light over a narrow wavelength range, and can emit light with a single polarization.

In the following description, the term “light” refers to electromagnetic radiation with wavelengths in the visible and non-visible portions of the electromagnetic spectrum, including infrared and ultra-violet portions of the electromagnetic spectrum.

### VCSELs with Sub-wavelength Gratings

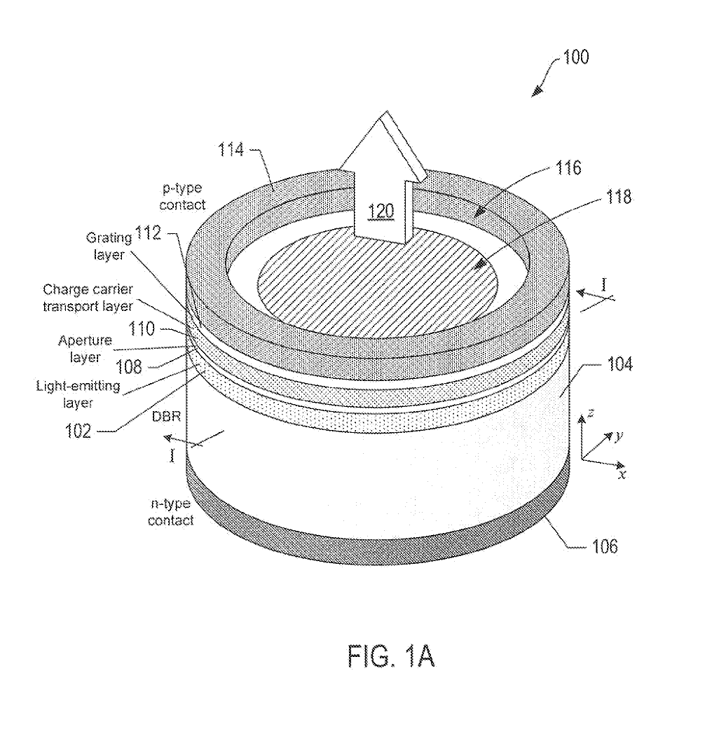

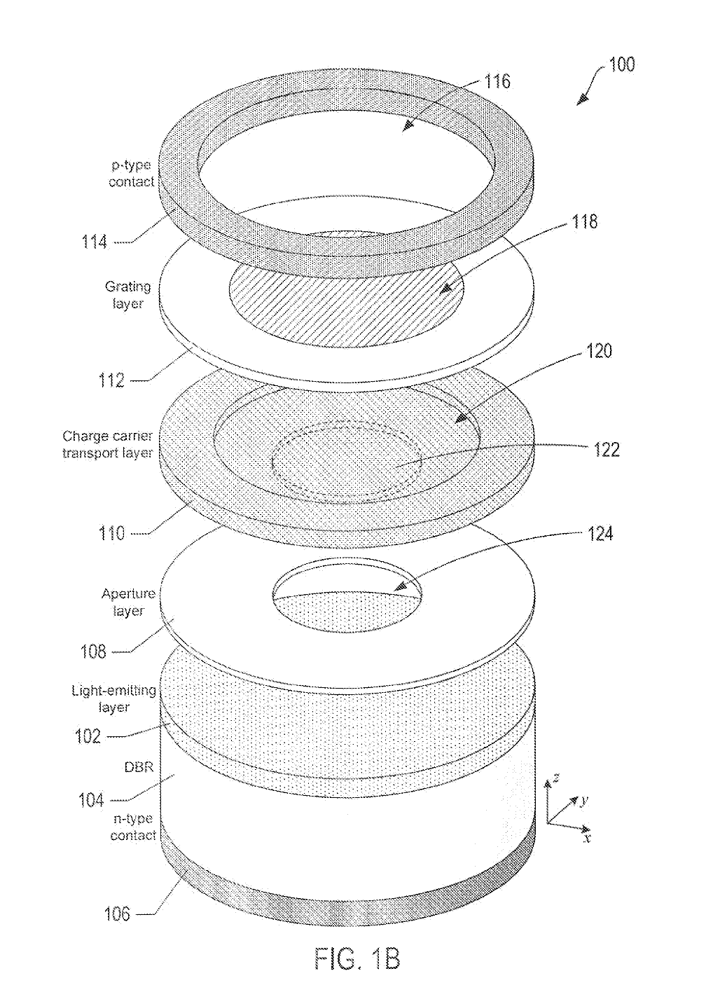

FIGS. 1A-1B show an isometric view and an exploded isometric view, respectively, of an example VCSEL 100. The VCSEL 100 includes a light-emitting layer 102 disposed on a distributed Bragg reflector (“DBR”) 104, which, in turn, is disposed on an n-type contact 106. The VCSEL 100 also includes an aperture layer 108 disposed on the light-emitting layer 102, a charge carrier transport layer 110 disposed on the aperture layer 108, a grating layer 112 disposed on the transport layer 110, and a ring-shaped p-type contact 114 disposed on the grating layer 112. As shown in the example of FIG. 1A, the p-type contact 114 includes a circular opening 116 exposing a SWG 118 of the grating layer 112. The opening 116 allows light generated by the VCSEL 100 to be emitted substantially perpendicular to the xy-plane of the layers, as indicated by directional arrow 120 (i.e., light is emitted from the VCSEL 100 through the opening 116 in the z-direction). The exploded isometric view of FIG. 1B reveals that the transport layer 110 includes a disk-shaped recessed region that forms a gap or air gap 120, described below, between the recessed region and the SWG 118. The transport layer 110 also includes a disk-shaped protrusion 122 that fills an opening or aperture 124 in the aperture layer 108. Note that embodiments are not limited to the openings 116 and 124 being circular. In other embodiments, the openings 116 and 124 can be square, elliptical or any other suitable shape.

The layers 102, 108, 110, and 112, DBR 104, and contracts 106 and 114 are composed of a various combinations of compound semiconductor materials. Compound semiconductors include III-V compound semiconductors and II-VI compound semiconductors. III-V compound semiconductors are composed of column Ma elements selected from boron (“B”), aluminum (“Al”), gallium (“Ga”), and indium (“In”) in combination with column Va elements selected from nitrogen (“N”), phosphorus (“P”), arsenic (“As”), and antimony (“Sb”). III-V compound semiconductors are classified according to the relative quantities of III and V elements, such as binary compound semiconductors, ternary compound semiconductors, and quaternary compound semiconductors. For example, binary semiconductor compounds include, but are not limited to, GaAs, GaAl, InP, InAs, and GaP; ternary compound semiconductors include, but are not limited to, In_{y}Ga_{y-1}As or GaAs_{y}P_{1-y}, where y ranges between 0 and 1; and quaternary compound semiconductors include, but are not limited to, InxGa₁₋ₓAs_{y}P_{1-y}, where both x and y independently range between 0 and 1. II-VI compound semiconductors are composed of column IIb elements selected from zinc (“Zn”), cadmium (“Cd”), mercury (“Hg”) in combination with VIa elements selected from oxygen (“0”), sulfur (“S”), and selenium (“Se”). For example, suitable II-VI compound semiconductors includes, but are not limited to, CdSe, ZnSe, ZnS, and ZnO are examples of binary II-VI compound semiconductors.

The layers of the VCSEL 100 can be formed using chemical vapor deposition, physical vapor deposition, or wafer bonding. The SWG 118 can be formed in the grating layer 112 using reactive ion etching, focusing beam milling, or nanoimprint lithography and the grating layer 112 wafer bonded to the transport layer 110.

In examples described herein, the DBR 104 and contact 106 are doped with n-type impurities while the contact 114 is doped with a p-type impurity. Alternatively, the DBR 104 and contact 106 can be doped with p-type impurities while the contact 114 is doped with an n-type impurity. P-type impurities are atoms incorporated into the semiconductor lattice that introduce vacancies called “holes” in electronic energy levels. These dopants are also called “electron acceptors,” and the holes are free to move. On the other hand, n-type impurities are atoms incorporated into the semiconductor lattice that introduce electrons to valence electronic energy levels. These dopants are called “electron donors.” In III-V compound semiconductors, column VI elements substitute for column V atoms in the III-V lattice and serve as n-type dopants, and column II elements substitute for column III atoms in the III-V lattice to serve as p-type dopants. Free electrons and holes are referred to as charge carriers, where by convention electrons have a negative charge while holes have positive charge. The aperture layer 108 can be composed of a dielectric material, such SiO₂ or Al₂O₃ or another material having a relatively larger electronic band gap than the other layers in the VCSEL 100.

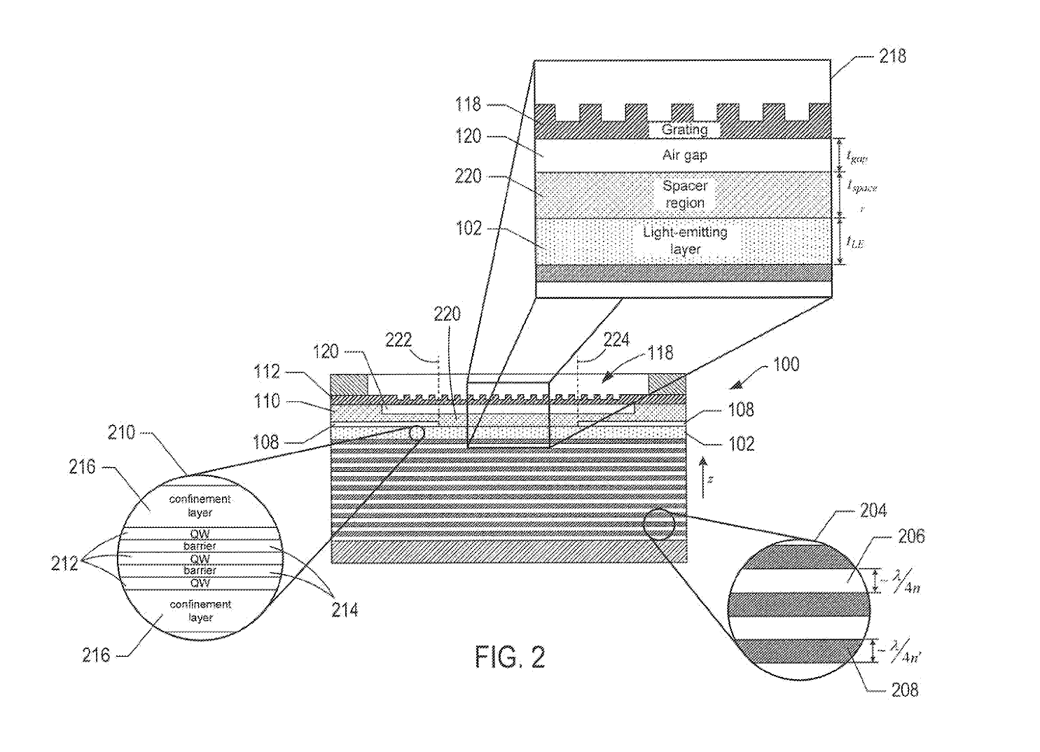

FIG. 2 shows a cross-sectional view of the VCSEL 100 along a line I-I, shown in FIG. 1A. The cross-sectional view reveals the structure of the individual layers. The DBR 104 is composed of a stack of DBR pairs 202 oriented parallel to the light-emitting layer 102. In practice, the DBR 104 can be composed of about 15 to about 40 or more DBR pairs. Enlargement 204 shows a sample portion of the DBR 104 and reveals that the layers of the DBR 104 each have a thickness of about λ/4n and λ/4n′, where λ is the vacuum wavelength of light emitted from the light-emitting layer 102, and n is the index of refraction of the DBR layers 206 and n′ is the index of refraction of the DBR layers 208. Dark shaded layers 208 represent DBR layers composed of a first semiconductor material, and light shaded layers 206 represent DBR layers composed of a second semiconductor material with the layers 206 and 208 having different associated refractive indices. For example, layers 204 can be composed of GaAs, which has an approximate refractive index of 3.6, and layers 206 can be composed AlAs, which has an approximate refractive index of 2.9.

FIG. 2 includes an enlargement 210 of the light-emitting layer 102 composed of three separate quantum-well layers (“QW”) 212 separated by barrier layers 214. The QWs 212 are disposed between confinement layers 216. The semiconductor material comprising the QWs 212 has a smaller electronic band gap than the barrier layers 214 and confinement layers 216. The layers 212, 214, and 216 are composed of different intrinsic semiconductor materials. For example, the QWs 212 can be composed of InGaAs (e.g., In_{0.2}Ga_{0.8}As), the barrier layers 214 can be composed of GaAs, and the confinement layers 216 can be composed of GaAlAs. Embodiments are not intended to be limited to the light-emitting layer 102 having three QWs. In other embodiments, the light-emitting layer 102 can have one, two, or more than three QWs.

FIG. 2 also includes an enlargement 218 of a central portion of the VCSEL 100. As shown and described above with reference to FIG. 1B, the transport layer 110 includes the disk-shaped recess that forms the gap 120 beneath the SWG 118. The disk-shaped protrusion 122 of the transport layer 110, also shown and described above with reference to FIG. 1B, substantially fills the aperture 124 of the aperture layer 108. The portion of the transport layer 110 located between the gap 120 and the light-emitting layer 102 and is bounded in the xy-plane by the aperture 124, as delimited by dashed lines 222 and 224, defines a spacer region 220. In the example of FIG. 2, the thicknesses of the gap 120, spacer region 220, and light-emitting layer 102 are denoted by t_{gap}, t_{spacer}, and t_{LE}. The thicknesses t_{gap}, t_{spacer}, and t_{LE} can be selected as described in greater detail below so that the gap 120, spacer region 220, and light-emitting layer 102 are transparent to the longitudinal mode of the VCSEL 100.

### Sub-Wavelength Gratings

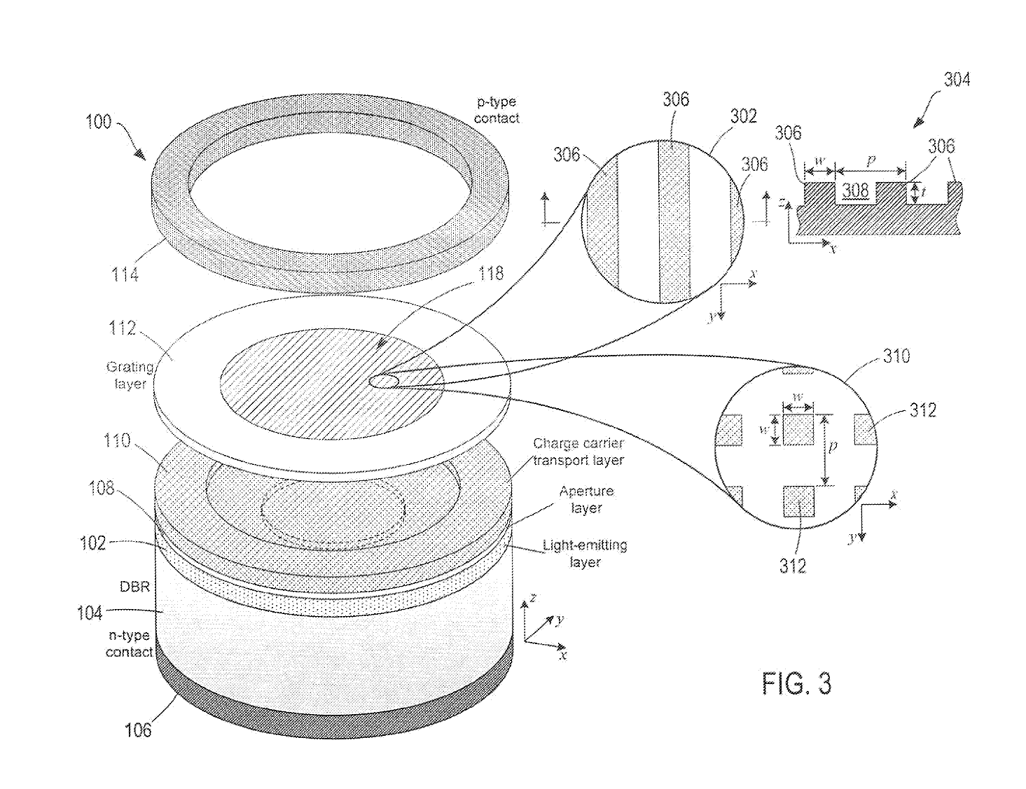

FIG. 3 shows an exploded isometric view of the VCSEL 100 with the grating layer 112 shown separated from the p-type contact layer 114 and the transport layer 110. The SWG 118 operates like a flat mirror for a selected wavelength of light. The SWG 118 can be a one-dimensional grating composed of regularly spaced wire-like portions of the layer 112 called “lines” separated by grooves. A one-dimensional SWG 118 reflects light with a particular polarization. FIG. 3 includes an enlargement 302 of a region of the SWG 118 that shows lines that extend in the y-direction and are periodically spaced in the x-direction. FIG. 3 also includes a cross-sectional view 304 of the enlargement 302 of lines 306 of thickness t, width w, and periodically separated by grooves 308 with period p. The line width w can range from approximately 10 nm to approximately 300 nm and the period p can range from approximately 20 nm to approximately 1 μm depending on the wavelength of the incident light. The wavelength of light reflected from the SWG 118 is determined by the line thickness and the duty cycle η defined as:

$$D C = \frac{w}{p}$$

The light reflected from the SWG 118 also acquires a phase shift determined by the line thickness and duty cycle.

The one-dimensional SWG 118 reflects TM or TE polarized light depending on the line thickness and duty cycle of the SWG 118. TE polarization corresponds to the electric field component of an incident electromagnetic wave being directed parallel to the lines of the SWG 118, and TM polarization corresponds to the electric field component of an incident electromagnetic wave directed perpendicular to the lines of the SWG 118. A particular line thickness and duty cycle may be suitable for reflecting TE polarized light but not for reflecting TM polarized light, while a different line thickness and duty cycle may be suitable for reflecting TM polarized light but not TE polarized light.

The SWG 118 is not intended to be limited to a one-dimensional grating. The SWG 118 can be implemented as a two-dimensional grating that operates like a polarization insensitive flat mirror for a selected wavelength. FIG. 3 includes an enlargement 310 that represents a portion of the SWG 118 with a two-dimensional sub-wavelength grating pattern. In enlargement 310, the SWG 118 is composed of posts 312, rather than lines, separated by grooves with the duty cycle and period the same in the x- and y-directions. Alternatively, the duty cycle can vary in the x- and y-directions. The posts of a two-dimensional SWG 118 can be square, rectangular, circular, elliptical or any other xy-plane cross-sectional shape. Alternatively, a two-dimensional SWG 118 can be composed of holes rather than posts. The holes can be square, circular, elliptical or any other suitable size and shape for reflecting light a particular wavelength.

The contrast between the refractive indices of the SWG 118 and air, changes the behavior of light as the light that moves between the SWG 118 and the air surrounding the SWG 118. The reflection coefficient characterizes the behavior of light that moves between the SWG 118 and air and is given by:

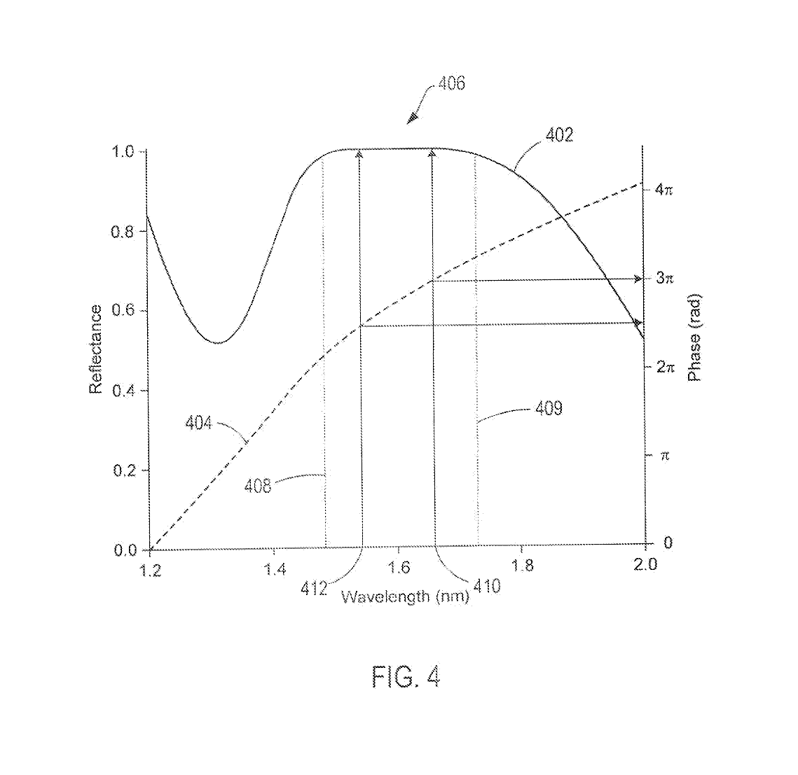

r(λ)=\sqrt{R(λ)}e^{iφ(λ)}

where R(λ) is the reflectance of the SWG, and φ(λ) is the phase shift in the light reflected off of the SWG. FIG. 4 shows a plot of reflectance and phase shift over a range of incident light wavelengths for an example one-dimensional SWG. Solid curve 402 corresponds to the reflectance R(λ), and dashed curve 404 corresponds to the phase shift φ(λ) produced by the SWG for incident light in the wavelength range of approximately 1.2 μm to approximately 2.0 μm. The SWG whose reflectance and phase shift are represented in FIG. 4 reflects TM polarized light over the wavelength range. The reflectance 402 and phase 404 curves were determined using MEEP, a finite-difference time-domain (“FDTD”) simulation software package used to model electromagnetic systems (see http://ab-initio.mit.edu/meep/meep-1.1.1.tar.gz). Due to the strong refractive index contrast between the SWG and air, the SWG has a broad spectral region of high reflectivity 406 between dashed-lines 408 and 410. However, curve 404 reveals that the phase of the reflected light varies across the entire high-reflectivity spectral region 406.

When the spatial dimensions of the period, line thickness, and line width is changed uniformly by a factor α, the reflection coefficient profile remains substantially unchanged, but the wavelength axis is scaled by the factor α. In other words, when a grating has been designed with a particular reflection coefficient R₀ at a free space wavelength λ₀, a different grating with the same reflection coefficient at a different wavelength λ can be designed by multiplying all the grating parameters, such as period, line thickness, and line width, by the factor α=λ/λ₀, giving r(λ)=r₀(λ/α)=r₀(λ₀). In particular, the grating parameters of a first SWG that reflects light of wavelength λ₀ with a high reflectivity can be used to create a second SWG that also reflects light with nearly the same high reflectivity but for a different wavelength λ based on a scale factor α=λ/λ₀. For example, consider a first one- dimensional SWG that reflects light with a wavelength λ₀≈1.67 μm 410 and has a line thickness, line width, and period represented by t, w, and p, respectively. Curves 402 and 404 reveal that the first SWG has a reflectance of approximate 1 and introduces a phase shift of approximately 3π rad in the reflected light. Now suppose a second one-dimensional SWG is desired with a reflectivity of approximately 1 but for the wavelength λ≈1.54 μm 412. The second SWG has a high reflectivity of approximately 1 with a line thickness, line width, and period αt, αw, and αp, respectively, where α=λ/λ₀≈0.945. According to curve 404, the second SWG introduces a smaller phase shift of approximately 2.5 πrad in the light reflected.

### VCSEL Operation

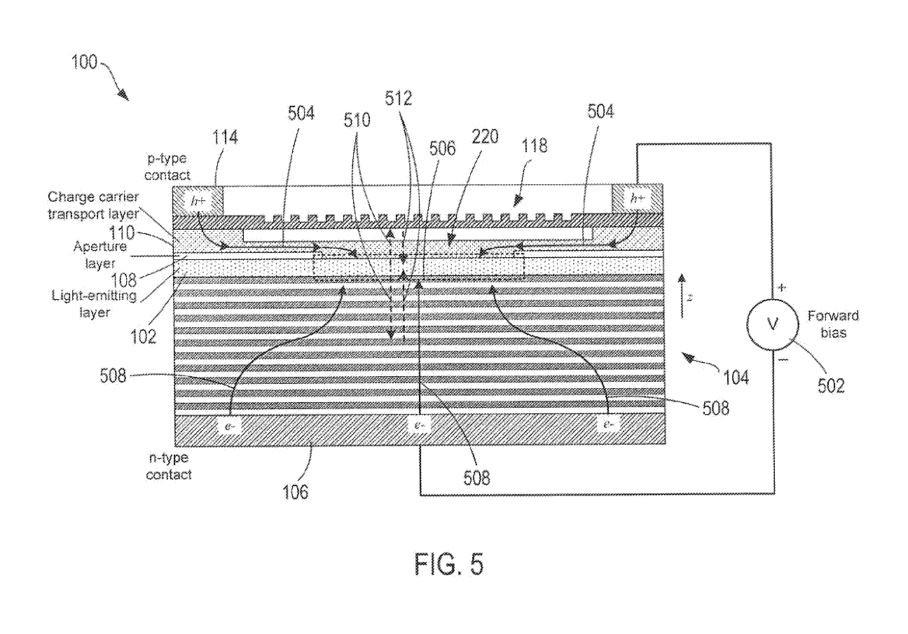

FIG. 5 shows a cross-sectional view of the VCSEL 100 connected to a voltage source 502. The voltage source 502 applies a forward bias to electronically pump the light-emitting layer 102. When no bias is applied to the VCSEL 100, the QWs of the light-emitting layer 102 have a relatively low concentration of electrons in corresponding conduction bands and a relatively low concentration of vacant electronic states, or holes, in corresponding valence bands. As a result, substantially no light is emitted from the light-emitting layer 102. In order to apply a forward-bias across the layers of the VCSEL array 100, the p-type contact 114 is attached to the positive terminal of the voltage source 502 and the n-type contact 106 is attached to the negative terminal of the voltage source 502. As shown in FIG. 5, the forward bias causes holes, denoted by h+, in the p-type contact 114 and electrons, denoted by e−, in the n-type contact 106 to drift towards the light-emitting layer 102. Directional arrows 504 represent paths holes take in reaching the light-emitting layer 102. Because the p-type contact 114 is ring shaped, holes drift into perimeter regions of the grating layer 112 and the transport layer 110. The aperture layer 108 restricts the path of the holes in the z-direction, which forces the holes to drift in the xy-plane of the transport layer 110 to the spacer region 220 and into a central region 506 of the light-emitting layer 102. The positive charge created by holes drifting into the spacer 220 and central 506 regions causes electrons injected into the n-type contact 106 and the

DBR 104 to drift toward the central region 506, as indicated by directional arrows 508. In summary, the aperture layer 108 confines the electrical current by forcing charge carriers to drift into the central region 506 of the light-emitting layer 102. Within the central region 506, electrons are injected into the conduction bands of the light-emitting layer 102 QWs while holes are injected into the valence bands of the QWs creating excess conduction band electrons and excess valence band holes in a process called “population inversion.” The electrons in the conduction band spontaneously recombine with holes in the valence band in a radiative process called “electron-hole recombination” or “recombination.” When electrons and holes recombine, light is initially emitted from the central region 506 in all directions over a broad range of wavelengths. As long as an appropriate operating voltage is applied in the forward-bias direction, electron and hole population inversion is maintained within the central region 506 and electrons spontaneously recombine with holes, emitting light in nearly all directions.

The SWG 118 of the grating layer 112 and the DBR 104 form a resonant cavity for light emitted approximately normal to the light-emitting layer 102, as indicated by directional arrows 510 and 512. The light reflected back into the light-emitting layer 102 stimulates the emission of more light from the light-emitting layer 102 in a chain reaction. Although the light-emitting layer 102 initially emits light over a broad range of wavelengths in all directions via spontaneous emission, the SWG 118 reflects light in a narrow wavelength range centered about a resonance wavelength, λᵣₑₛ, back into the light-emitting layer 102 causing stimulated emission of light with the wavelength λᵣₑₛ in the z-direction. The light reflected back and forth in the resonant cavity in the z-direction with the resonance wavelength λᵣₑₛ is also referred to as the longitudinal, axial, or z-axis mode. Over time, the gain in the light-emitting layer 102 becomes saturated by the longitudinal mode and the longitudinal mode begins to dominate the light emissions from the light-emitting layer 102 while other modes decay. In other words, electromagnetic waves with wavelengths outside of the narrow range of wavelengths surrounding the resonance wavelength λᵣₑₛ are not reflected back and forth between the SWG 118 and the DBR 104 and leak out of the VCSEL array 100 eventually decaying as the resonance wavelength or longitudinal mode supported by the resonant cavity begins to dominate.

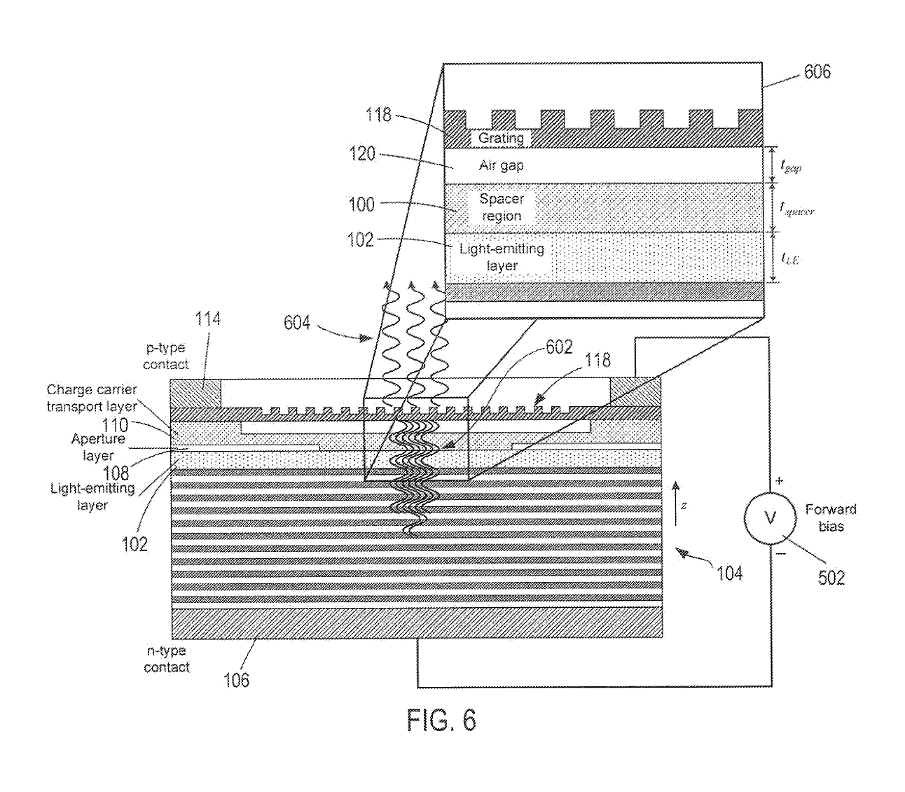

FIG. 6 shows a representation of standing electromagnetic waves that form within the resonant cavity created by the SWG 118 and the DBR 104. The dominant longitudinal mode reflected between the SWG 118 and the DBR 104 is amplified as the electromagnetic waves sweep back and forth across the light-emitting layer 102 producing standing electromagnetic waves 602 with the wavelength λᵣₑₛ that terminate within the SWG 118 and extend into the DBR 104. Ultimately, a substantially coherent beam of light 604 with the resonance wavelength λᵣₑₛ emerges from the SWG 118. Light emitted from the light-emitting layer 102 penetrates the DBR 104 and the SWG 118 and adds a contribution to the round trip phase of the light in the resonant cavity.

FIG. 6 also includes enlargement 606 of a central portion of the VCSEL 100, as describe above with reference to FIG. 2. The thickness t_{gap} of the gap 120 and thickness t_{spacer} of the spacer region 220 are selected so that the layers 120 and 220 are transparent to the resonance wavelength Ares, and the thickness t_{LE} of the light-emitting layer 102 is selected to establish resonance with the resonance wavelength λᵣₑₛ. In order to ensure that the layers 120 and 220 are transparent to the resonance wavelength λᵣₑₛ and layer 102 has resonance with the wavelength λᵣₑₛ, the thicknesses of the layers 120, 220, and 102 can be selected based on the following conditions:

$${t}_{gap} \approx \frac{{λ}_{res}}{4} + \frac{α {λ}_{res}}{2} , \\ {t}_{spacer} \approx \frac{β {λ}_{res}}{2 {n}_{s}} , and$$

$${t}_{LE} \approx \frac{k {λ}_{res}}{2 {n}_{L}}$$

where α and β are real numbers greater than or equal to 1, nₛ is the refractive index of the transport layer 110, n_{L} is the refractive index of the light-emitting layer 102, and k is a positive integer.

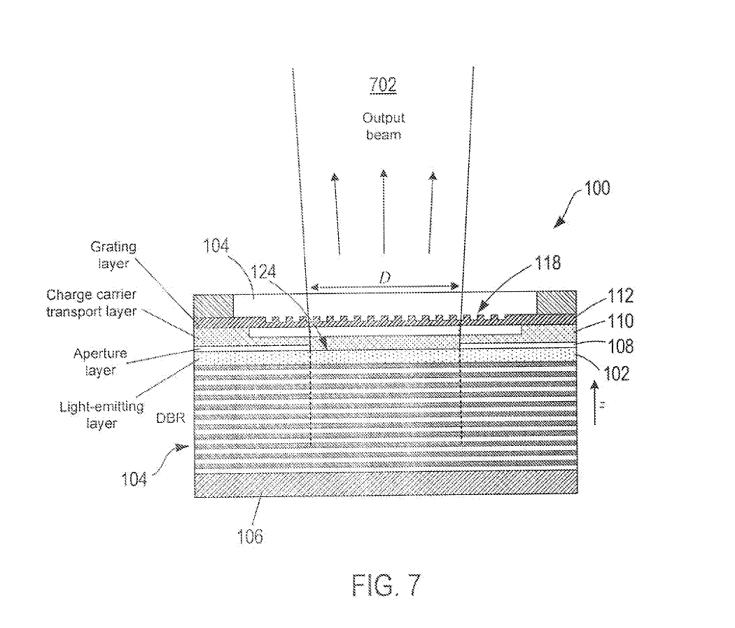

Light confined in the z-direction between SWG 118 and the DBR 104 is also confined in the xy-plane by the aperture 124 in the aperture layer 108. In other words, the aperture 124 substantially prevents the longitudinal mode from spreading away from the central region 506 of SWB 118. As a result, a beam of light emitted from the VCSEL 100 is confined by the aperture 124. FIG. 7 shows a cross-sectional view of the VCSEL 100 with an output beam 702. The beam 702 is output through the SWG 118 with the confinement of the beam 702 determined by the diameter D of the aperture 124. The beam 702 passes through the SWG 118 with a beam diameter slightly larger than the diameter D and spreads out as the beam 702 travels away from the VCSEL 100. Degradation of the beam 702 due to diffraction at the aperture 124 edges and the degree to which the beam 702 remains confined away from the VCSEL 100 are determined by the diameter D.

As described above with reference to FIG. 4, if the SWG 118 is a one-dimensional grating the SWG 118 reflects TE or TM polarized light back into the resonant cavity and the beam 702 emitted from the VCSEL 100 is either TE or TM polarized. As the gain becomes saturated, only modes with the polarization selected by the SWG 118 are amplified. Electromagnetic waves emitted from the light-emitting layer 102 that do not have the polarization selected by the SWG 118 leak out of the VCSEL 100 with no appreciable amplification. In other words, longitudinal modes with polarizations other than those selected by the SWG 118 decay and are not present in the emitted beam 702. Ultimately, only longitudinal modes polarized in the direction selected by the SWG 118 are emitted in the beam 702.

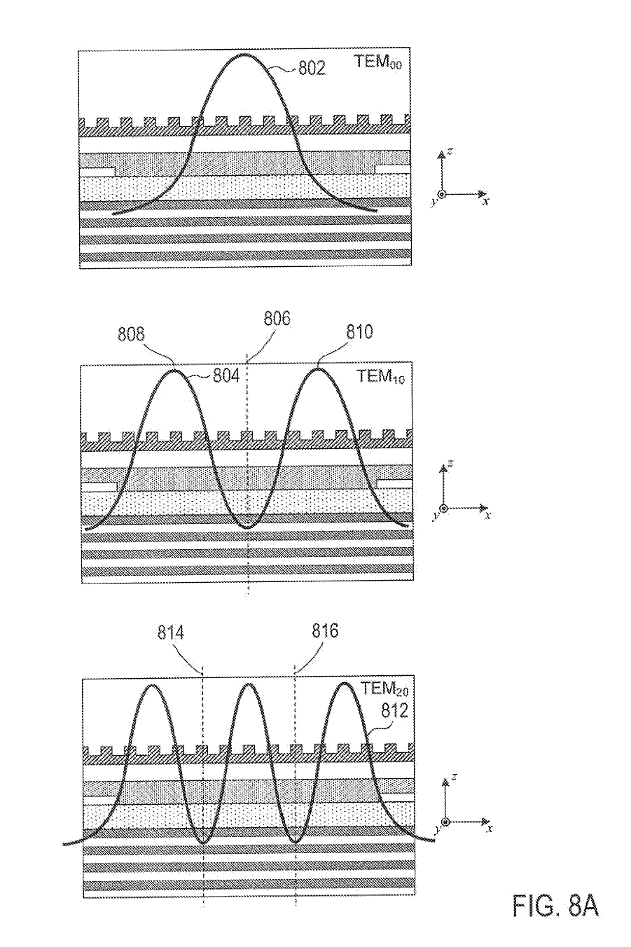

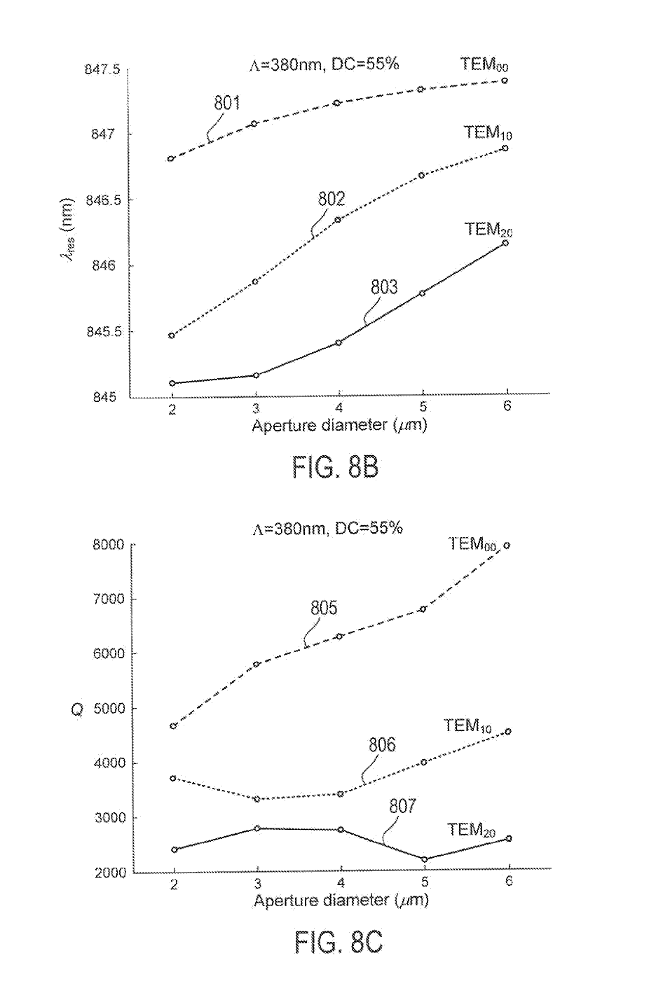

The aperture 124 in the aperture layer 108 also plays a role in adjusting the resonance wavelength and in selecting the transverse modes in the beam 702. Each transverse mode corresponds to a particular electromagnetic field pattern that lies within a plane perpendicular to the beam 702 axis or resonant cavity. Transverse modes are denoted by TEMₙₘ, where n and m subscripts are the integer number of transverse nodal lines in the x- and y- directions, respectively. FIG. 8A shows examples of three xz-plane intensity profiles associated with three transverse modes formed in the resonant cavity between the SWG 118 and the DBR 104. In FIG. 8A, TEM₀₀ mode represented by curve 802 has no nodes and lies almost entirely within the aperture 124, which indicates that much of the electromagnetic radiation associated with the TEM₀₀ mode is concentrated in the central region of the resonant cavity. TEM₁₀ mode represented by curve 804 has one node 806 in the x-direction that separates two intensity peaks 808 and 810, which indicates that the electromagnetic radiation intensity is divided into two segments in the x-direction. TEM₂₀ mode represented by curve 812 has two nodes 814 and 816, which indicates that the electromagnetic radiation intensity is divided into three segments in the x-direction. FIGS. 8B-8C show plots that represent how the resonance wavelength and quality factor associated with the resonant cavity can be affected by the aperture diameter 124. The results presented in FIGS. 8B-8C were obtained using MEEP. In

FIG. 8B, curves 801-803 represent the resonance wavelengths associated with the TEM₀₀, TEM₁₀, and TEM₂₀ modes, respectively, as a function of the aperture 124 diameter. Curves 801-803 indicate that the resonance wavelength supported by the resonant cavity is different for the TEM₀₀, TEM₁₀, and TEM₂₀ modes, and the resonance wavelength associated with the TEM₀₀, TEM₁₀, and TEM₂₀ modes increases with the diameter of the aperture 124, where the mode TEM₀₀ has the least amount of increase. In FIG. 8C, curves 805-807 represent the resonance wavelengths associated with the TEM₀₀, TEM₁₀, and TEM₂₀ modes as a function of the aperture 124 diameter. Curves 805-807 indicate that the quality factor Q of the resonant cavity is different for the TEM₀₀, TEM₁₀, and TEM₂₀ modes with the resonant cavity having a considerable larger quality factor for the TEM₀₀ mode than for the TEM₁₀ and TEM₂₀ modes. The stark difference in quality factors between the TEM₀₀ mode and the TEM₁₀ and TEM₂₀ modes may be the result of the TEM₁₀ and TEM₂₀ modes spreading beyond the aperture 124. Returning to FIG. 8A, notice that the TEM₀₀ mode lies substantially within the aperture 124 while portions of the TEM₁₀ and TEM₂₀ modes are spread in the x-direction beyond the diameter of the aperture 124. As a result, during gain saturation, because the TEM₀₀ mode lies within aperture 124, the TEM₀₀ mode is more strongly supported by the resonant cavity resulting in a larger quality factor. By contrast, portions of the TEM₁₀ and the TEM₂₀ modes lie outside the aperture 124 resulting in low quality factors and a decrease in gain saturation.

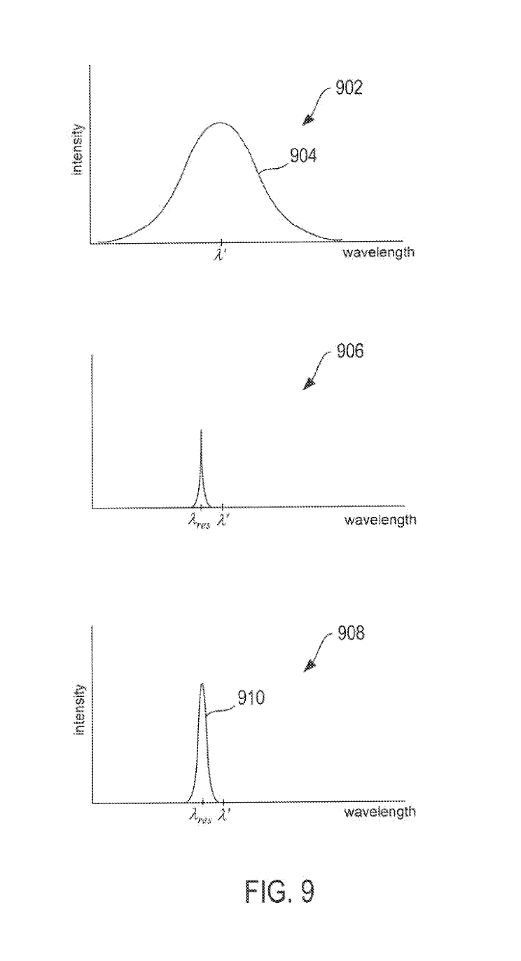

As described above, the resonant cavity and the aperture 124 diameter can be used in combination to select the longitudinal mode to be emitted from the VCSEL 100. FIG. 9 shows example intensity profile plots associated with the light-emitting layer 102 and light emitted from the VCSEL 100. In example plot 902, an intensity or gain profile 904 represents a broad range of wavelengths of light initially emitted from the light-emitting layer 102. The intensity profile 904 is centered about a wavelength λ′. Example plot 906 represents a longitudinal resonant cavity mode) λᵣₑₛ supported by the resonant cavity formed by the SWG 118 and the DBR 104 and the aperture 124 diameter. The light-emitting layer 102 makes available a range of wavelengths represented by the intensity profile 904 out of which the resonant cavity and the aperture 124 select the longitudinal mode with the resonance wavelength) λᵣₑₛ. Example plot 908 shows an intensity peak 910 that represents a narrow range of wavelengths centered about centered about the resonance wavelength λᵣₑₛ. Light within this narrow range is amplified within the resonant cavity and ultimately emitted from the VCSEL 100 through the SWG 118.

Note that the height and cavity length of the VCSEL 100 is considerably shorter than the height and cavity length of a conventional VCSEL with two DBRs. For example, a typical VCSEL has two DBRs with each DBR having about 15 to about 40 DBR pairs, which corresponds to each DBR having a thickness of about 5 μm to about 6 μm. By contrast, an SWG has a thickness ranging from about 0.2 μm to about 0.3 μm and has an equivalent or higher reflectivity.

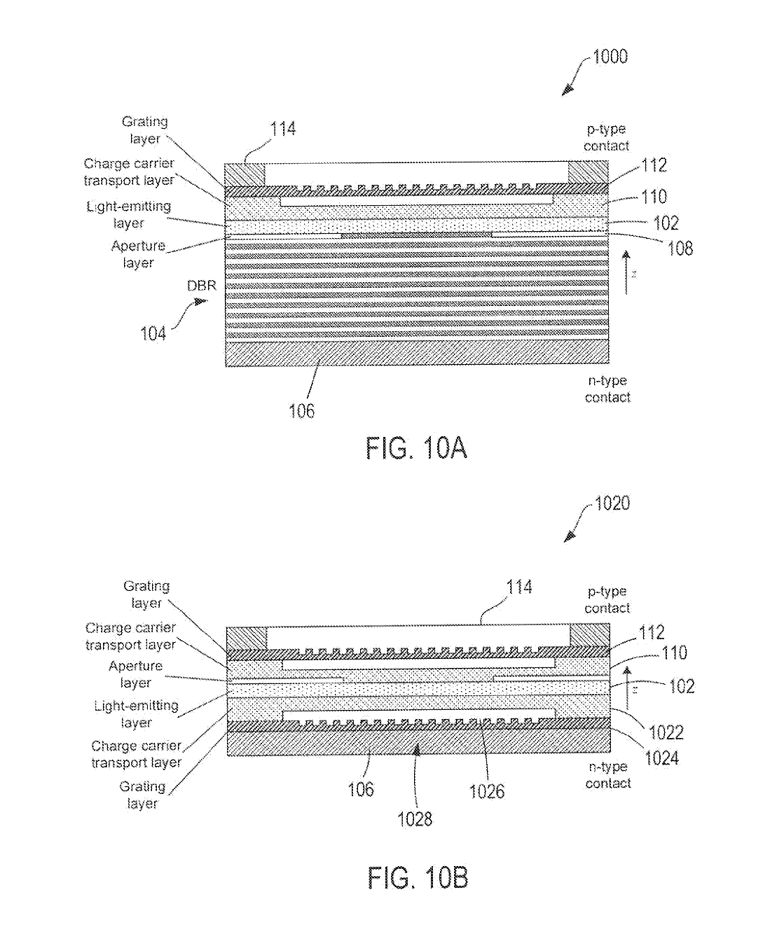

Returning to FIGS. 1 and 2, the aperture layer 108 is disposed between the transport layer 110 and the light-emitting layer 102. However, VCSEL embodiments are not intended to be so limited. The aperture layer 108 can be disposed between the light-emitting layer 102 and the DBR 104. FIG. 10A shows cross-sectional view of an example VCSEL 1000 that is similar to the VCSEL 100 except the aperture layer 108 is disposed between the light-emitting layer 102 and the DBR 104. In other embodiments, a VCSEL can have two or more apertures layers. For example, a VCSEL can have a first aperture layer disposed between the transport layer and the light-emitting layer, as is the case with the VCSEL 100, and the VCSEL can have second aperture layer disposed between the light-emitting layer and the DBR, as is the case with the VCSEL 1000. Alternatively, a VCSEL can have two or more aperture layers between the transport layer and the light-emitting layer or have two or more aperture layers between the light-emitting layer and the DBR. In other embodiments, the DBR 104 can be replaced by a second SWG and a charge carrier transport layer. FIG. 10B shows a cross-sectional view of an example VCSEL 1020 the same p-type contact 114, grating layer 112, transport layer 110, aperture layer 108, light-emitting layer 102, and p-type contact 106 as the VCSEL 100 except the DBR 104 of the VCSEL 100 has been replaced by a second charge carrier transport layer 1022 and grating layer 1024. The transport layer 1004 may include an gap 1026 and the grating layer 1024 includes an SWG 1028 with substantially the same grating pattern as the SWG 118 of the grating layer 112.

### VCSEL Arrays

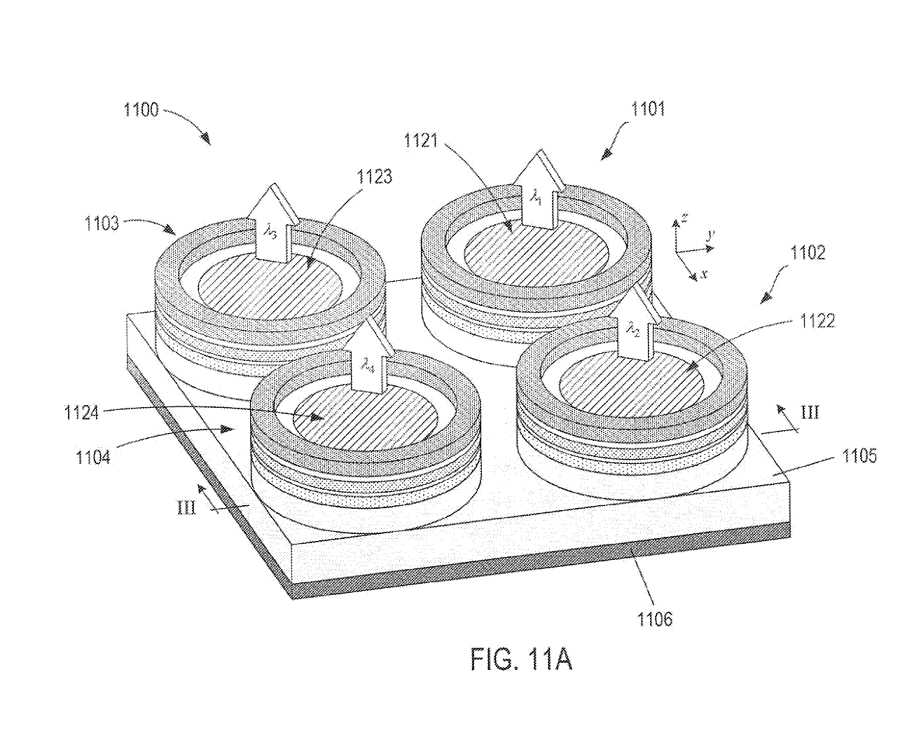

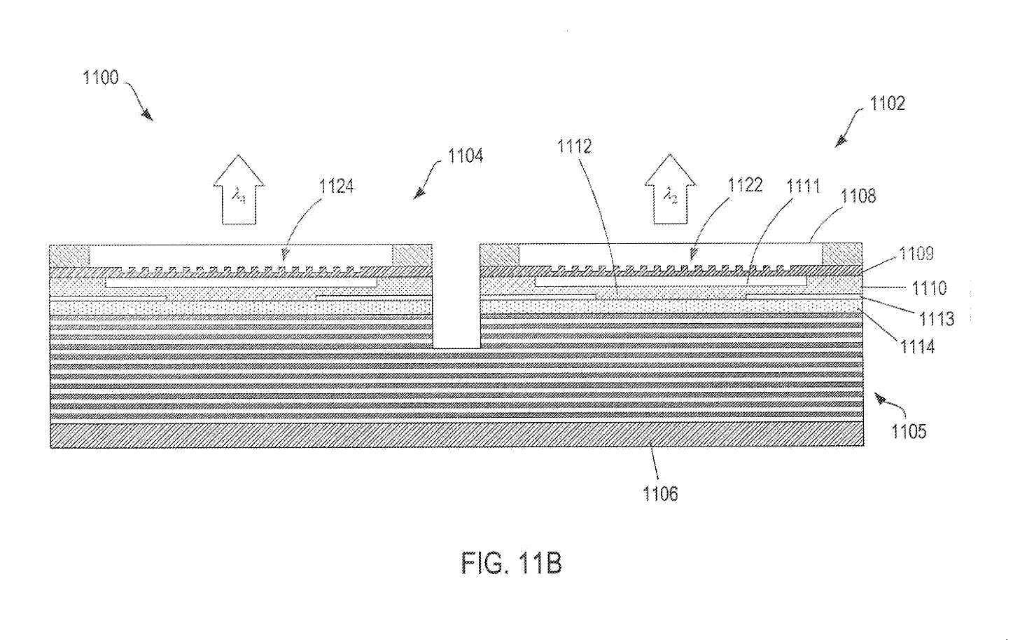

FIG. 11A shows an isometric view of an example VCSEL array 1100. The VCSEL array 1100 includes four separate VCSELs 1101-1104. Each VCSEL is configured as described above, but the four VCSELs 1101-1104 share a DBR 1105 and a n-type contact 1106. FIG. 11B shows a cross-sectional view of the VCSELs 1102 and 1104 of the VCSEL array 1100 along a line III-III shown in FIG. 11A. FIG. 11B reveals that each of the VCSELs of the VCSEL array 1100 is similar to the VCSEL 100 described above. For example, the VCSEL 1102 includes a ring-shaped contact 1108 disposed on a grating layer 1109, which is disposed on a charge carrier transport layer 1110. Like the transport layer 108 of the VCSEL 100, the transport layer 1110 includes a disk-shaped recessed region that forms an gap 1111 and a disk-shaped protrusion 1112 that forms a spacer region in an aperture of an aperture layer 1113. The aperture layer 1113 is disposed on a light-emitting layer 1114 which is disposed on a portion of the DBR 1105.

The grating layer of each VCSEL includes an SWG to reflect a particular wavelength with a high reflectance, as described above with reference to FIG. 4. For example, returning to FIG. 11A, the VCSELs 1101-1104 include grating layers with SWGs 1121-1124 to reflect different wavelengths λ₁, λ₂, λ₃, and λ₄, respectively. The SWGs 1121-1124 form four separate resonant cavities with the DBR 1105. For example, as shown in FIG. 2B, the SWG 1122 and the DBR 1105 form a resonant cavity of the VCSEL 1102 and the SWG 1124 and the DBR 1105 form a separate resonant cavity of the VCSEL 1104. Each of the VCSELs 1101-1104 is operated in the same manner as the VCSEL 100 described above to emit light with resonance wavelengths λ₁, λ₂, λ₃, and λ₄, respectively.

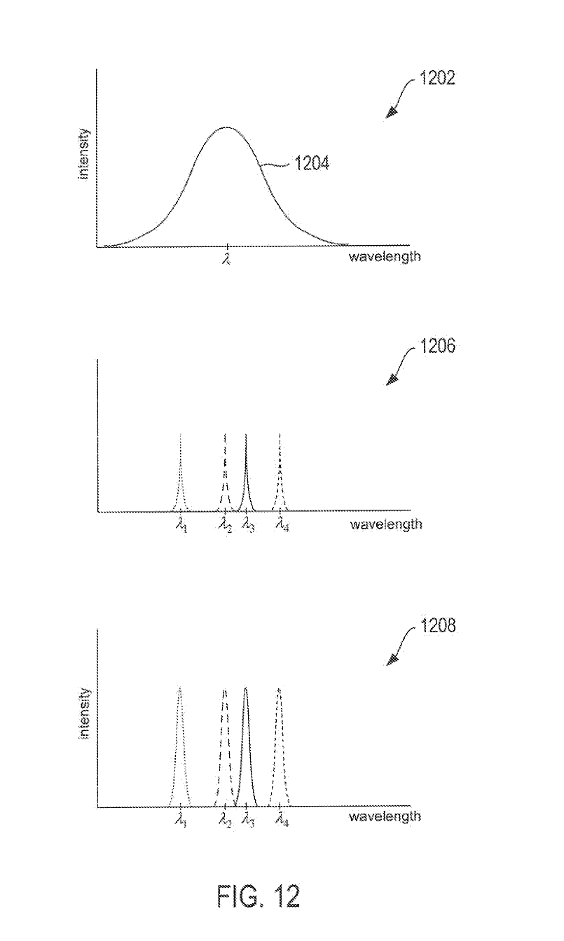

The light-emitting layers of the VCSELs 1101-1104 can be composed of the same material to emit light over the same range of wavelengths, but each SWG of the VCSELs 1101-1104 selects a different longitudinal mode of the light emitted from the light-emitting layers. FIG. 12 shows an example plot 1202 of an intensity or gain profile 1204 of light emitted from the light-emitting layers of the VCSELs 1101-1104. FIG. 12 includes an example plot 1206 of four different resonant cavity modes, each resonant cavity mode is associated with a different VCSEL of the VCSEL array 1100. For example, peaks in the plot 1206 represent single longitudinal cavity modes λ₁, λ₂, λ₃, and λ₄ associated with the four VCSELs 1101-1104, respectively. The resonant cavity of each VCSEL selects the corresponding longitudinal mode represented in the plot 1206. Each longitudinal mode is amplified within the cavity of the associated VCSEL and emitted as described above for the VCSEL 100. For example, plot 1208 shows the intensity profiles of the resonance wavelengths emitted from the four VCSELs of the VCSEL array 1100. As shown in plot 1208, each longitudinal mode can be emitted with substantially the same intensity.

The arrangement and number of VCSELs in a VCSEL array can vary depending on the desired number of separate light beams and the arrangement of light beams and is not intended to be limited to the arrangement of four VCSELs shown in FIG. 11. Note that although the VCSEL array is described as each VCSEL emits a different wavelength, embodiments are not intended to be so limited. In other embodiments, any combination of VCSELs, including all of the VCSELs of the VCSEL array, can emit the same wavelength. Also, the SWGs 1121-1124 can be any combination of one- and two-dimensional gratings so that the VCSELs 1101-1104 can emit a combination of polarized and/or unpolarized beams of light.

The foregoing description, for purposes of explanation, used specific nomenclature to provide a thorough understanding of the disclosure. However, it will be apparent to one skilled in the art that the specific details are not required in order to practice the systems and methods described herein. The foregoing descriptions of specific examples are presented for purposes of illustration and description. They are not intended to be exhaustive of or to limit this disclosure to the precise forms described. Obviously, many modifications and variations are possible in view of the above teachings. The examples are shown and described in order to best explain the principles of this disclosure and practical applications, to thereby enable others skilled in the art to best utilize this disclosure and various examples with various modifications as are suited to the particular use contemplated. It is intended that the scope of this disclosure be defined by the following claims and their equivalents:

1. A surface-emitting laser including:
a grating layer having a sub-wavelength grating to form a resonant cavity with a reflective layer for a wavelength of light to be emitted from a light-emitting layer;
an aperture layer having an aperture, the aperture layer disposed within the resonant cavity; and
a charge carrier transport layer disposed between the grating layer and the light-emitting layer, the transport layer having a gap adjacent to the sub-wavelength grating and a spacer region between the gap and the light-emitting layer, the spacer region and gap dimensioned to be substantially transparent to the wavelength, the aperture layer to direct charge carriers to enter a region of the light-emitting layer adjacent to the aperture, and the aperture to confine optical modes to be emitted from the light-emitting layer.

2. The laser of claim 1, wherein the aperture layer is disposed between the transport layer and the light-emitting layer such that a portion of the transport layer is in contact with the light-emitting layer through the aperture.

3. The laser of claim 1, wherein the aperture layer is disposed between the light-emitting layer and the reflective layer such that a portion of the reflective layer is in contact with the light-emitting layer through the aperture.

4. The laser of claim 1, wherein the reflective layer is a distributed Bragg reflector.

5. The laser of claim 1 including a first ring-shaped contact disposed on the grating layer, the ring-shaped contact including an opening through which the sub-wavelength grating is exposed, and a second contact disposed on the reflective layer, wherein the first contact is composed of a p-type (n-type) material and the second contact is composed of an n-type (p-type) material.

6. The laser of claim 1, wherein the transport layer includes a recessed region that forms the gap adjacent to the sub-wavelength grating.

7. A laser array including:
a reflective layer; and
a number of surface-emitting lasers, each laser including:
a light-emitting layer;
a grating layer with a sub-wavelength grating to form a resonant cavity with the reflective layer for a wavelength of light to be emitted from the light-emitting layer;
an aperture layer with an aperture disposed within the resonant cavity; and
a charge carrier transport layer disposed between the grating layer and the light-emitting layer, wherein the aperture layer and transport layer are configured as described in claim 1.

8. A surface-emitting laser including:
a resonant cavity to have resonance with a wavelength of light to be emitted from a light-emitting layer disposed within the resonant cavity;
a charge carrier transport layer disposed within the resonant cavity and in contact with the light-emitting layer; and
an aperture layer including an aperture, the aperture layer disposed adjacent to the light-emitting layer, the transport layer having a gap adjacent to a first reflective layer of the resonant cavity and a spacer region between the gap and the light-emitting layer, the spacer region and gap dimensioned to be substantially transparent to the wavelength, the aperture layer to direct charge carriers to enter a region of the light-emitting layer adjacent to the aperture, and the aperture to confine optical modes to be emitted from the light-emitting layer.

9. The laser of claim 8, wherein the aperture layer is disposed between the transport layer and the light-emitting layer such that a portion of the transport layer is in contact with the light-emitting layer through the aperture.

10. The laser of claim 8, wherein the aperture layer is disposed between the light-emitting layer and a reflective layer of the resonant cavity such that a portion of the reflective layer is in contact with the light-emitting layer through the aperture.

11. The laser of claim 8, wherein the first reflective layer is a grating layer with a sub-wavelength grating adjacent to the gap.

12. The laser of claim 8, wherein the resonant cavity includes a distributed Bragg reflector as a second reflective layer.

13. The laser of claim 8 including a first ring-shaped contact disposed on the grating layer, the ring-shaped contact including an opening through which the sub-wavelength grating is exposed, and a second contact disposed on the reflective layer, wherein the first contact is composed of a p-type (n-type) material and the second contact is composed of an n-type (p-type) material.

14. The laser of claim 8, wherein the transport layer includes a recessed region that forms the gap adjacent to the sub-wavelength grating.

15. A laser array including:
a reflective layer; and
a number of surface-emitting lasers, each laser including:
a resonant cavity to have resonance with a wavelength of light to be emitted from a light-emitting layer disposed within the resonant cavity;
a charge carrier transport layer disposed within the resonant cavity and in contact with the light-emitting layer; and
an aperture layer including an aperture, the aperture layer disposed adjacent to the light-emitting layer, wherein the aperture layer and transport layer are configured as described in claim 1.
